(19) United States
(12) Patent Application Publication
(10) Pub. No.: US 2026/0082733 A1
(43) Pub. Date: Mar. 19, 2026

(54) WAVELENGTH-CONVERTED LIGHT-EMITTING DIODES WITH VERTICAL DIE GEOMETRY

(71) Applicant: Lumileds LLC, San Jose, CA (US)

(72) Inventors: Jeff DiMaria, Scotts Valley, CA (US); Antonio Lopez-Julia, Vaals (NL); Yu-Chen Shen, Sunnyvale, CA (US)

(73) Assignee: Lumileds LLC, San Jose, CA (US)

(21) Appl. No.: 18/890,258

(22) Filed: Sep. 19, 2024

(51) Int. Cl. H01L 33/20; H01L 33/42; H01L 33/50

(52) U.S. Cl. CPC H10H 20/819; H10H 20/833; H10H 20/851

(57) ABSTRACT

An LED includes first/second doped layers with active region(s) therebetween emitting a first wavelength, and is arranged in a vertical die geometry with a reflective first electrical contact on a first LED surface. A wavelength converter absorbs the first wavelength and emits a second, longer wavelength. Some examples include a transparent second electrical contact on a second LED surface or angled LED sidewalls, and the wavelength converter is on the LED surface and the angled LED sidewalls. Some other examples include a second electrode on LED side surfaces extending beyond a second LED surface to form a cavity, with the wavelength converter on the second LED surface at least partly filling the cavity.

### FIELD OF THE INVENTION

The field of the present invention relates to light-emitting diodes (LEDs). Wavelength-converted LEDs are described herein having a vertical die geometry.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

In some instances the light directly emitted by the active region of an LED can comprise its entire output; such an LED can be referred to as a direct emitter, or a direct-emitting LED. The LEDs of the present disclosure are combined with one or more wavelength-converting materials (also referred to herein as “phosphors”) that absorb light emitted by the LED active region and in response emit light of a longer wavelength. Hereinafter the term LED shall denote such wavelength-converted LEDs, unless explicitly stated otherwise. For wavelength-converted LEDs (sometimes referred to as phosphor-converted LEDs), the fraction of the light emitted by the LED active region that is absorbed by the phosphors depends on the amount of phosphor material in the optical path of the light emitted by the LED active region, for example on the concentration of phosphor material in a phosphor layer disposed on or around the LED and the thickness of the layer. Wavelength-converted LEDs can be designed so that all of the light emitted by the LED active region is absorbed by one or more phosphors, in which case the overall output of the wavelength-converted LED is entirely from the one or more phosphors. In such cases one or more phosphors can be selected, for example, to emit light in one or more corresponding narrow spectral regions that are not efficiently generated directly by the LED active region, or to emit white light having a desired color temperature or desired color-rendering properties. Alternatively, wavelength-converted LEDs can be designed so that only a portion of the light emitted by the LED active region is absorbed by the phosphor(s), in which case the emission from the wavelength-converted LED is a mixture of light emitted by the LED active region and light emitted by the phosphor(s). By suitable choice of LED, phosphor(s), and phosphor composition, such a wavelength-converted LED can be designed to emit, for example, white light having a desired color temperature or desired color-rendering properties.

Multiple LEDs can be formed together on a single substrate to form an array. Such arrays can be employed to form active illuminated displays, such as those employed in, e.g., smartphones and smart watches, computer or video displays, augmented- or virtual-reality displays (i.e., visualization systems), or signage, or to form adaptive illumination sources, such as those employed in, e.g., automotive headlights, street lighting, camera flash sources, or flashlights (i.e., torches). An array having one or several or many individual devices per millimeter (e.g., device pitch or spacing of about a millimeter, a few hundred microns, less than 50 or 100 microns, or even smaller, and/or separation between adjacent devices less than 100 microns or only a few tens of microns or even less) typically is referred to as a miniLED array or a microLED array (alternatively, a μLED array).

### SUMMARY

A wavelength-converted light-emitting device includes a semiconductor light-emitting diode (LED), a wavelength converter, and first and second electrical contacts. The LED includes first and second doped layers with one or more active regions between them. The active region(s) emit first output light in a first output wavelength range. The first doped layer is between a first LED surface and the active region(s); the second doped layer is between a second LED surface and the active region(s). LED sidewalls connect the first and second LED surfaces. The wavelength converter is positioned on at least the second LED surface and absorbs at least a portion of the first output light that enters the wavelength converter and emits second output light in a second output wavelength range that is longer than the first output wavelength range. The first electrical contact is positioned on the first LED surface, reflective over the first output wavelength range, and in electrical contact with the first doped layer.

In a first set of examples the LED sidewalls form an angle less than about 70° with either the first or second LED surface, and the wavelength converter is positioned on the second LED surface and the LED sidewalls. The second electrical contact is positioned on at least a portion of the second LED surface or on a portion of the LED sidewalls, transparent over the first output wavelength range, and in electrical contact with the second doped layer.

In a second set of examples the second electrical contact is positioned on at least a portion of the LED sidewalls, is reflective over the first output wavelength range, is in electrical contact with the second doped layer, and extends beyond the second LED surface to form a cavity bounded by the second substrate surface and the second electrical contact. An electrically insulating layer on a portion of the LED sidewalls separates the second electrical contact from the first electrical contact, the first doped layer, and the active layer(s). The wavelength converter at least partially fills the cavity.

Objects and advantages pertaining to wavelength-converted LEDs may become apparent upon referring to the example embodiments illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example wavelength-converted LED.

FIGS. 2A and 2B show, respectively, cross-sectional and top schematic views of an example array of LEDs.

FIG. 3 is a top schematic view of an example LED array and an enlarged section of 3x3 LEDs of the array.

FIGS. 4 through 6 are schematic cross-sectional views of three examples among a first set of examples of a wavelength-converted LED.

FIGS. 7 and 8 are schematic cross-sectional views of two examples among a second set of examples of a wavelength-converted LED.

The embodiments depicted are shown only schematically; all features may not be shown in full detail or in proper proportion; for clarity certain features or structures may be exaggerated or diminished relative to others or omitted entirely (e.g., exaggerated thicknesses of optical coatings or transparent conductive layers); the drawings should not be regarded as being to scale unless explicitly indicated as being to scale. In the drawings some schematic illustrations of example structures of various devices and assemblies described herein may be shown with precise right angles and straight lines, but it is to be understood that such schematic illustrations may not reflect real-life process limitations or defects. Such process limitations or defects can cause the features to look not so "ideal" when any of the structures described herein are examined using, e.g., scanning electron microscopy (SEM) images or transmission electron microscope (TEM) images. In such images of real structures, possible processing limitations or defects might be visible, e.g., not-perfectly straight edges of materials, tapered vias or other openings, inadvertent rounding of corners or variations in thicknesses of different material layers. There may be other limitations or defects not listed here that can occur within the field of device fabrication. The embodiments shown are only examples and should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter.

For purposes of the present disclosure and appended claims, any arrangement of a layer, surface, substrate, diode structure, wavelength converter, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, a layer, coating, structure, or material described as “transparent” or “substantially transparent” shall exhibit, over one or more pertinent wavelength ranges, a level of optical transmission that is sufficiently high, or a level of optical loss (due to absorption, scattering, reflection, or other loss mechanism) that is sufficiently low, that the light-emitting device can function within operationally acceptable parameters (e.g., output power or luminance, conversion or extraction efficiency, or other figures-of-merit including any described below). Similarly, a layer, coating, structure, or material described as “reflective” shall exhibit reflectivity that is sufficiently high, over one or more pertinent wavelength ranges, that the light-emitting device can function within operationally acceptable parameters such as those listed above or described below.

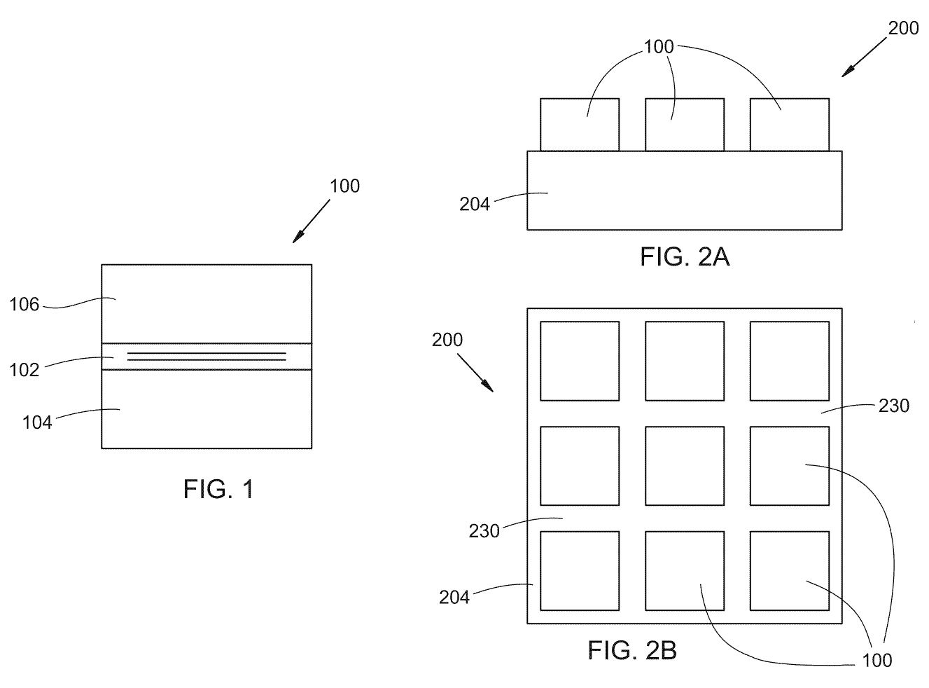

FIG. 1 shows an example of an individual wavelength-converted LED 100 comprising a semiconductor diode structure 102 (i.e., LED 102) disposed on a substrate 104 and a wavelength converter 106 (e.g., a phosphor layer) disposed on the LED 102. In the present disclosure “wavelength-converted LED 100” or simply “LED 100” shall denote a wavelength-converted LED generally arranged as in FIG. 1 (including both the LED 102 and the wavelength converter 106), while “semiconductor LED 102” or simply “LED 102” shall denote only the semiconductor diode structure 102 (without the wavelength converter 106). The semiconductor LED 102 typically comprises an active region disposed between n-type and p-type doped semiconductor layers; examples of an active region can include a junction between the n- and p-type layers, or one or more active layers between the n- and p-type layers (e.g., quantum well, multi-quantum well, quantum dots, and so forth). Application of a suitable forward bias across the LED 102 results in emission of first output light from the active region in a first output wavelength range. The wavelength of the emitted first output light is determined by the composition and structure of the active region and composition of the doped layers.

The LED 102 can be, for example, a III-Nitride LED that emits red, green, blue, violet, or ultraviolet light from its active region. Diode structures formed from any other suitable material system and that emit any other suitable wavelength of light can be employed. Other suitable material systems can include, e.g., III-Phosphide materials, III-Arsenide materials, other binary, ternary, or quaternary mixtures, compounds, or alloys of gallium, aluminum, indium, nitrogen, phosphorus, arsenic, or other III-V materials, or II-VI materials, or Group IV materials.

Any suitable wavelength-converting materials may be used for or incorporated into the wavelength converter 106, depending on the desired optical output from the wavelength-converted LED 100. Some examples can include, e.g., suitably doped ceramics, phosphor particles embedded in a suitable matrix material (e.g., a silicone or other polymer), or quantum dots. The wavelength converter 106 absorbs at least a portion of the first output light that enters the wavelength converter and emits second output light in a second output wavelength range that is longer than the first output wavelength range

FIGS. 2A and 2B show, respectively, cross-sectional and top views of an array 200 of LEDs 100 disposed on a substrate 204. Such an array can include any suitable number of LEDs arranged in any suitable manner. In the illustrated example the array is depicted as being formed monolithically on a shared substrate; alternatively, an array of LEDs can be formed from separate individual LEDs (e.g., singulated devices that are assembled onto an array substrate). In an array of wavelength-converted LEDS, individual wavelength-converting pixels 106 can be positioned on each semiconductor diode pixel 102; alternatively, a continuous layer of wavelength-converting material can be disposed across multiple semiconductor LEDs 102. LEDs 100 in the array 200 may be spaced apart from each other by streets, lanes, or trenches 230. Arrays of the present disclosure can include light barriers (e.g., reflective, scattering, and/or absorbing) in the lanes 230 between adjacent LEDs 102, wavelength converters 106, or both; those light barriers can in some instances include one or more electrodes, metal layers, dielectric layers, multilayer coatings, and so forth on sidewalls of the LEDs. Some examples of those are described below.

Individual LEDs 100 of an array 200 can optionally incorporate or be arranged in combination with a lens or other optical element located adjacent to or disposed on the LED or wavelength converter. Such an optical element (not shown in the drawings) can be referred to as a “primary optical element”. Instead or in addition, an LED array 200 (for example, mounted on an electronics board) can be arranged in combination with secondary optical elements such as waveguides, lenses, or both (not shown in the drawings) for use in an intended application. Other primary or secondary optical elements of any suitable type or arrangement can be included for each pixel or for an array of pixels, as needed or desired, depending on the desired application (e.g., display, illumination source, and so forth).

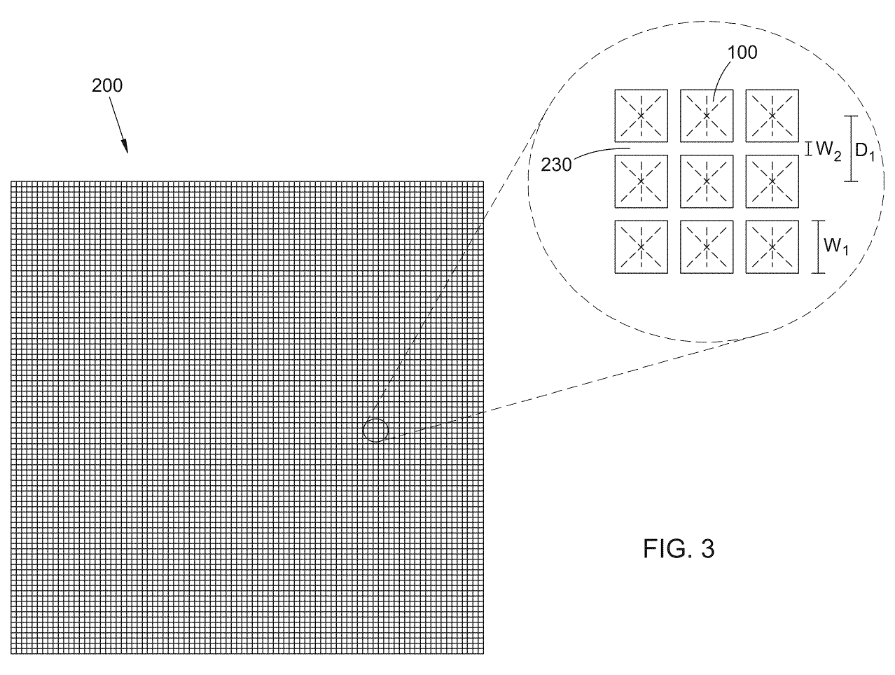

Although FIGS. 2A and 2B show a 3x3 array of nine LEDs, LED arrays can include for example on the order of 10¹, 10², 10³, 10⁴, or more LEDs, e.g., as illustrated schematically in FIG. 3. In some examples individual LEDs 100 (i.e., pixels) may have widths w₁ (e.g., side lengths) in the plane of the array 200, for example, less than or equal to 1 millimeter (mm), less than or equal to 500 microns, less than or equal to 100 microns, or less than or equal to 50 microns. LEDs 100 in the array 200 may be spaced apart from each other by the streets, lanes, or trenches 230 having a width w₂ in the plane of the array 200 of, for example, hundreds of microns, less than or equal to 100 microns, less than or equal to 50 microns, less than or equal to 20 microns, less than or equal to 10 microns, or less than or equal to 5 microns. The pixel pitch or spacing D₁ is the sum of w₁ and w₂. LEDs having dimensions w₁ in the plane of the array (e.g., side lengths) of less than or equal to about 200 microns are typically referred to as microLEDs or µLEDs, and an array of such microLEDs may be referred to as a microLED array. LEDs having dimensions w₁ in the plane of the array (e.g., side lengths) of between about 0.10 millimeters and about 1.0 millimeters are typically referred to as miniLEDs, and an array of such miniLEDs may be referred to as a miniLED array. In some examples larger LEDs can be employed. Although the illustrated examples show rectangular pixels arranged in a symmetric, regular array, the pixels and the array may have any suitable shape or arrangement, whether symmetric or asymmetric, regular or irregular. Multiple separate arrays of LEDs can be combined in any suitable arrangement in any applicable format to form a larger combined array or display.

One source of inefficiency of a wavelength-converted LED is that a fraction of the first output light that does not exit the LED 102 through a first LED surface and enter the wavelength converter 106. Some of that first output light might exit the LED 102, e.g., through LED sidewalls or a second LED surface opposite the first LED surface. Another source of inefficiency is propagation of second output light emitted by the wavelength converter 106 toward the LED 102, instead of exiting the wavelength-converting 106 structure to propagate away from the wavelength-converted LED 100.

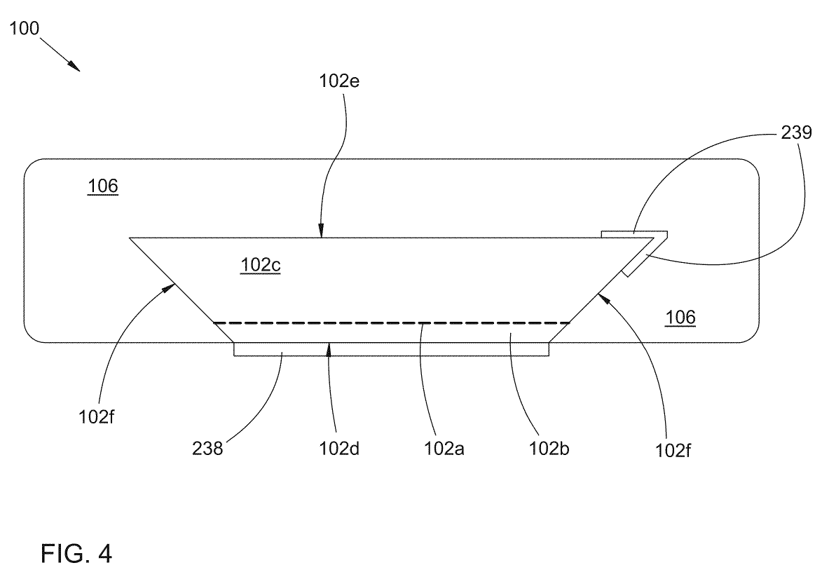

Schematic cross-sectional views of various examples of wavelength-converted LEDs 100 are shown in FIGS. 4 through 8 in which various adaptations are implemented for increasing, e.g., the fraction of the first output light that exits the LED 102 and enters the wavelength converter 106, or the fraction of the second output light that exits the wavelength converter 106 and propagates away from the wavelength-converted LED 100.

Each wavelength-converted LED 100 of the present disclosure includes a semiconductor LED 102, a wavelength converter 106, and first and second electrical contacts 238 and 239, respectively.

The LED 102 has opposite first and second LED surfaces 102d and 102e, respectively, and LED sidewalls 102f connecting the first and second LED surfaces 102d/102e. The LED 102 includes one or more light-emitting active regions 102a, a first doped semiconductor layer 102b between the first LED surface 102d and the active region(s), and a second doped semiconductor layer 102c between second LED surface 102e and the active region(s) 102a. In many examples the doped layer 102b can be a p-doped layer and the doped layer 102c can be an n-doped layer. The LED 102 can include one or more doped or undoped III-V, II-VI, or Group IV semiconductor materials, or mixtures, alloys, or compounds thereof. The one or more light-emitting active regions 102a are arranged between the doped layers 102b/102c in any suitable way to emit first output light in a first output wavelength range, e.g., including one or more quantum wells or multi-quantum wells, quantum dots of any suitable size, composition, or structure, or one or more tunnel junctions of any suitable composition, thickness, or structure. The first output wavelength range can include UV light or visible light.

One or more wavelength-converted LEDs 100 can be positioned on the substrate 204 which can optionally include electrical traces or interconnects, or CMOS or other circuitry for connecting to the electrical contacts 238/239 and providing drive current to the LED 102, and can be formed from any suitable materials. LEDs 100 of the present disclosure are arranged with a vertical die contact geometry, as illustrated schematically in the example cross-sectional views of FIGS. 4 through 8. In a vertical die geometry, the first electrical contact 238 is reflective over the first output wavelength range and positioned against the first LED surface 102d, while the wavelength converter 106 is positioned against the second LED surface 102e. The reflective first contact 238 reflects any incident first output light and redirects it toward the wavelength converter 106. The wavelength-converted vertical die LED 100 can be a single device (e.g., as in FIG. 1), or can be one device among many similarly arranged wavelength-converted LEDs 100 in an array 200 (e.g., as in FIGS. 2A, 2B, or 3). In some examples individual LEDs 102 (pixels) in an array 200 of multiple LEDs can be individually addressable (i.e., selectively operable); in some examples the LEDs 102 can be addressable as part of a group or subset of the pixels in the array; in some examples the LEDs are not addressable.

The wavelength converter 106 is positioned on at least the second LED surface 102e, and absorbs at least a portion of the first output light that enters the wavelength converter 106 and emits second output light in a second output wavelength range that is longer than the first output wavelength range. Any one or more suitable materials can be employed in the wavelength converter 106, such as phosphor particles of any suitable size or composition, or quantum dots of any suitable size, composition, or structure. Phosphor particles or quantum dots typically are dispersed, embedded, or coated in a suitable transparent medium (e.g., silicones, metal oxides/nitrides, or semiconductor oxides/nitrides). A wavelength converter 106 with quantum dots can be advantageously employed in LED arrays with spacing of less than 10 microns or device separation less than a few microns or sub-micron. In some examples the first output wavelength range includes one or more UV or visible wavelengths, the second output wavelength range includes one or more visible wavelengths, and the wavelength converter 106 is arranged to absorb substantially all of the entering first output light, so that overall output of the wavelength-converted light-emitting device 100 includes light in only the second wavelength range. In some other examples both the first and second output wavelength ranges include visible wavelengths, and the wavelength converter 106 is arranged to absorb only a portion of the entering first output light, so that overall output of the wavelength-converted light-emitting device 100 includes light in both the first and second wavelength ranges. In some examples the overall output of the wavelength-converted LED 100 can be white light having a selected color temperature or having specified color rendering properties.

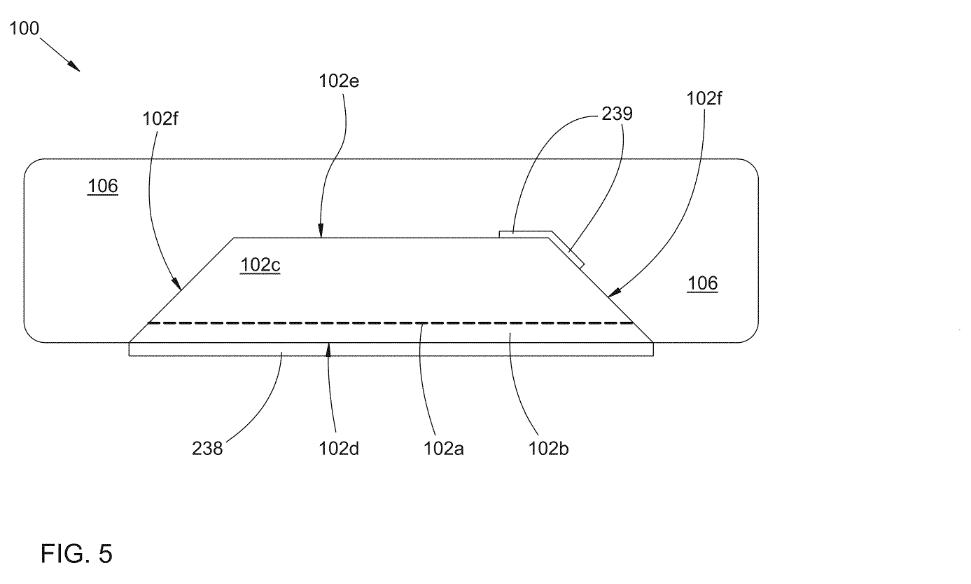

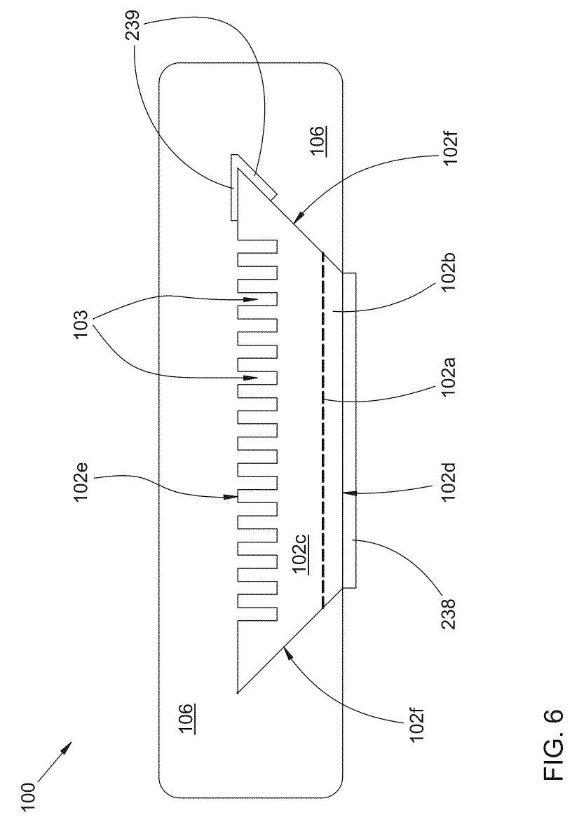

FIGS. 4-6 illustrate schematically three examples among a first set of examples of a vertical die wavelength-converted LED 100. In those and similar examples the LED sidewalls 102f form an angle less than about 70° with either the first LED surface 102d (forming an upright truncated pyramid, as in FIG. 5) or the second LED surface 102e (forming an inverted truncated pyramid, as in FIGS. 4 and 6). The wavelength converter 106 is positioned on the second LED surface 102e and the LED sidewalls 102f, so that any first output light exiting the LED 102 through those surfaces enters the wavelength converter 106. The first electrical contact 238 is positioned on the first LED surface 102d, is reflective over the first output wavelength range, and is in electrical contact with the first doped layer 102b. The second electrical contact 239 is electrically isolated from the first contact 238, and is on at least a portion of the second LED surface 102e or on a portion of the LED sidewalls 102f; in some examples the second contact 239 can extend across the entire second LED surface 102e. The second contact 239 is transparent over the first output wavelength range and is in electrical contact with the second doped layer 102c. In some examples the second electrical contact 239 can include a transparent conductive oxide (TCO) layer in direct contact with the second doped layer 102c. Examples of suitable TCO materials can include one or more of indium tin oxide (ITO), indium zinc oxide (IZO), or other transparent conductive oxides.

The angled sidewalls 102f increase the fraction of the first output light that exits the LED 102 and enters the wavelength converter 106. In some examples the LED sidewalls 102f form an angle between about 40° and about 50° with either the first or second LED surface 102d/102e. In some examples the thickness of the LED 102 (i.e., the total thickness of the first and second doped layers 102b/102c and the active layer(s) 102a) is less than about 5 microns, less than about 3 microns, less than about 2 microns, or about equal to 1 micron, which can further increase the fraction of the first output light that exits the LED 102 to enter the wavelength converter 106.

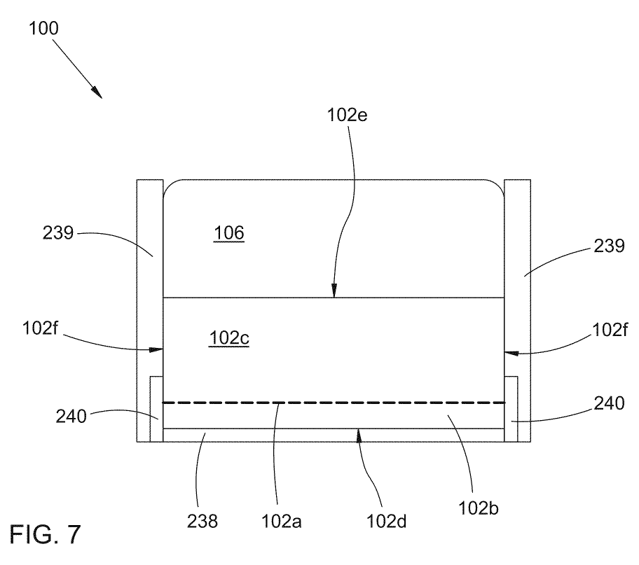

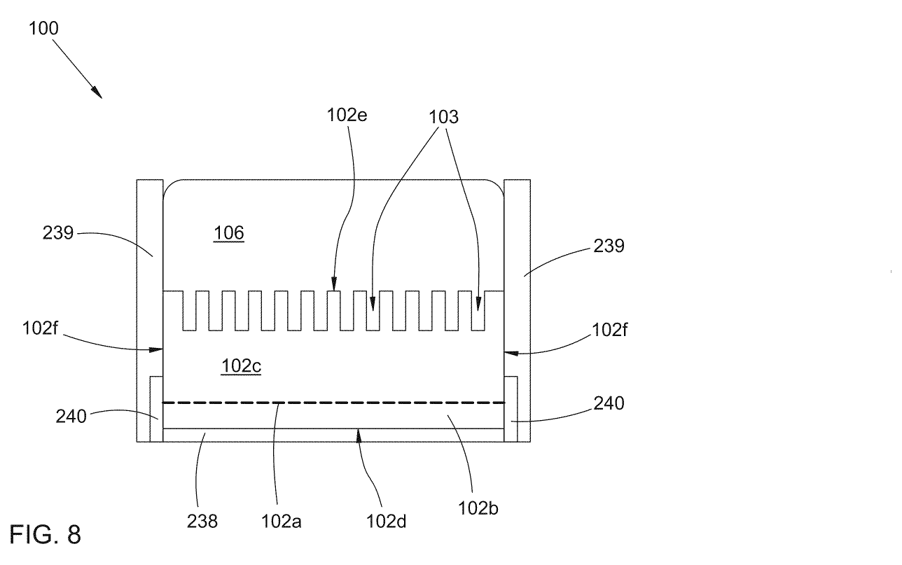

FIGS. 7 and 8 illustrate schematically two examples among a second set of examples of a vertical die wavelength-converted LED 100. In those and similar examples the first electrical contact 238 is positioned on the first LED surface 102d, is reflective over the first output wavelength range, and is in electrical contact with the first doped layer 102b. The second electrical contact 239 is electrically isolated from the first contact 238, is on at least a portion of the LED sidewalls 102f, is reflective over the first output wavelength range, and is in electrical contact with the second doped layer 102c. In some examples the LED sidewalls 102f are substantially perpendicular to the LED surfaces 102d/102e. In some other examples the LED sidewalls 102f form an acute angle with either the first LED surface 102d (forming an upright truncated pyramid) or the second LED surface 102e (forming an inverted truncated pyramid).

The second contact 239 extends beyond the second LED surface so as to form a cavity bounded by the second substrate surface 102e and the second electrical contact 239. Any suitably conductive and reflective material can be employed for the contact 239 that is also sufficiently strong and rigid to form the cavity. Metallic materials, e.g., aluminum or silver or other metals of alloys, can be employed. A first electrically insulating layer 240 is positioned on a portion of the LED sidewalls 102f and separates the second electrical contact 239 from the first electrical contact 238, the first doped layer 102b, and the active layer(s) 102a. The insulating layer 240 can include any one or more suitable dielectric materials, e.g., metal or semiconductor oxides or nitrides. The wavelength converter 106 is positioned on the second LED surface 102e and at least partially fills the cavity.

In some examples arranged as in FIGS. 4-6 or as in FIGS. 7 and 8, additional structural adaptations can be employed to increase the fraction of the first output light that exits the LED 102 and enters the wavelength converter 106. In some examples, the second LED surface 102e can include patterning, roughening, scattering or diffractive elements, or a set of microlenses for coupling the first output light from the LED 102 into the wavelength converter 106. In some other examples, the second LED surface 102e can include a plurality of holes or depressions 103 in the second doped layer 102c that are at least partly filled with material of the wavelength converter 106. A wavelength converter 106 that includes quantum dots can be advantageously employed in such an example, because the small size of the quantum dots enables them to fill the holes or depressions 103. In the example of FIG. 6 the LED 102 forms an inverted truncated pyramid; a plurality of holes or depressions 103 filled with material of the wavelength converter 106 can also be provided in other examples (not shown) wherein the LED 102 forms an upright truncated pyramid. In the example of FIG. 8 the LED sidewalls 102f are perpendicular to the LED surfaces 102d/102e; a plurality of holes or depressions 103 filled with material of the wavelength converter 106 can also be provided in other examples (not shown) wherein the LED sidewalls 102f form an acute angle with either the first LED surface 102d or the second LED surface 102e.

In examples arranged as in FIGS. 4-6 or as in FIGS. 7 and 8, the reflective contact 238 can be arranged in any suitable way and incorporate any one or more suitable materials for providing electrical contact to the first doped layer 102b and reflectivity over the output wavelength range. In some examples the first contact 238 includes a metallic layer in direct contact with the first doped layer 102b. Any one or more metals or alloys can be employed, e.g., aluminum or silver. In some other examples the first contact 238 includes a metallic layer (including any suitable metal(s) or alloy(s)), a second electrically insulating layer (different from the insulating layer 240) between the metallic layer and the LED 102, and one or more electrically conductive vias that connect the metallic layer to the first doped layer 102b. Some of those examples can further include a transparent conductive oxide (TCO) layer (e.g., ITO or IZO) between the second insulating layer and the first LED surface 102b. The TCO layer is in direct contact with the first doped layer 102b, and the first set of via(s) connects the metallic layer to the TCO layer (and thus to the first doped layer 102b). In some examples that second insulating layer can include a dielectric multilayer reflector (e.g., a distributed Bragg reflector) that is reflective over the first output wavelength range.

In addition to the preceding, the following example embodiments fall within the scope of the present disclosure or appended claims. Any given Example below that refers to multiple preceding Examples shall be understood to refer to only those preceding Examples with which the given Example is not inconsistent, and to exclude implicitly those preceding Examples with which the given Example is inconsistent.

Example 1. A wavelength-converted light-emitting device comprising: (a) a semiconductor light-emitting diode (LED) having opposite first and second LED surfaces and LED sidewalls connecting the first and second LED surfaces and forming an angle less than about 70° with either the first or the second LED surface, the LED including (i) one or more light-emitting active regions arranged so as to emit first output light in a first output wavelength range, (ii) a first doped semiconductor layer between the first LED surface and the one or more active regions, and (iii) a second doped semiconductor layer between second LED surface and the one or more active regions; (b) a wavelength converter, positioned on the second LED surface and the LED sidewalls, that absorbs at least a portion of the first output light that enters the wavelength converter and emits second output light in a second output wavelength range that is longer than the first output wavelength range; (c) a first electrical contact on the first LED surface, the first contact being reflective over the first output wavelength range and in electrical contact with the first doped layer; and (d) a second electrical contact, electrically isolated from the first contact, on at least a portion of the second LED surface or on a portion of the LED sidewalls, the second contact being transparent over the first output wavelength range and in electrical contact with the second doped layer.

Example 2. The device of Example 1 wherein the LED sidewalls form an angle between about 40° and about 50° with either the first or second LED surface.

Example 3. The device of any one of Examples 1 or 2 wherein the first contact includes a metallic layer in direct contact with the first doped layer.

Example 4. The device of any one of Examples 1 or 2 wherein the first contact includes a metallic layer, an electrically insulating layer between the metallic layer and the LED, and one or more electrically conductive vias that connect the metallic layer to the first doped layer.

Example 5. The device of Example 4 wherein the first contact includes a transparent conductive oxide (TCO) layer between the insulating layer and the first LED surface and in direct contact with the first doped layer, the first set of one or more vias connecting the metallic layer to the TCO layer.

Example 6. The device of any one of Examples 4 or 5 wherein the insulating layer includes a dielectric multilayer reflector.

Example 7. The device of any one of Examples 1 through 6 wherein thickness of the LED is less than 5 microns, less than about 3 microns, less than about 2 microns, or about equal to 1 micron.

Example 8. A wavelength-converted light-emitting device comprising: (a) a semiconductor light-emitting diode (LED) having opposite first and second LED surfaces and LED sidewalls connecting the first and second LED surfaces, the LED including (i) one or more light-emitting active regions arranged so as to emit first output light in a first output wavelength range, (ii) a first doped semiconductor layer between the first LED surface and the one or more active regions, and (iii) a second doped semiconductor layer between second LED surface and the one or more active regions; (b) a first electrical contact on the first LED surface, the first contact being reflective over the first output wavelength range and in electrical contact with the first doped layer; (c) a second electrical contact, electrically isolated from the first contact, on at least a portion of the LED sidewalls, the second contact being in electrical contact with the second doped layer and reflective over the first output wavelength range, and extending beyond the second LED surface so as to form a cavity bounded by the second substrate surface and the second electrical contact; (d) a first electrically insulating layer on a portion of the LED sidewalls that separates the second electrical contact from the first electrical contact, the first doped layer, and the one or more active layers; and (e) a wavelength converter, positioned on the second LED surface and at least partially fills the cavity, that absorbs at least a portion of the first output light that enters the wavelength converter and emits second output light in a second output wavelength range that is longer than the first output wavelength range.

Example 9. The device of Example 8 wherein the LED sidewalls form an acute angle with either the first or the second LED surface.

Example 10. The device of any one of Examples 8 or 9 wherein the first contact includes a metallic layer in direct contact with the first doped layer.

Example 11. The device of any one of Examples 8 or 9 wherein the first contact includes a metallic layer, a second electrical insulating layer between the metallic layer and the LED, and one or more electrically conductive vias that connect the metallic layer to the first doped layer through the second insulating layer.

Example 12. The device of Example 11 wherein the first contact includes a transparent conductive oxide (TCO) layer between the second insulating layer and the first LED surface and in direct contact with the first doped layer, the first set of one or more vias connecting the metallic layer to the TCO layer.

Example 13. The device of any one of Examples 11 or 12 wherein the second insulating layer includes a dielectric multilayer reflector.

Example 14. The device of any one of Examples 1 through 13 wherein the second LED surface includes patterning, roughening, scattering or diffractive elements, or a set of microlenses for coupling the first output light from the LED into the wavelength converter.

Example 15. The device of any one of Examples 1 through 14 wherein the second LED surface includes a plurality of holes or depressions in the second doped layer at least partly filled with material of the wavelength converter.

Example 16. The light-emitting device of any one of Examples 1 through 15 wherein (i) the LED includes one or more doped or undoped III-V, II-VI, or Group IV semiconductor materials, or mixtures, alloys, or compounds thereof, (ii) the first doped layer is a p-doped layer and the second doped layer is an n-doped layer, or (iii) the one or more active regions include quantum dots, one or more quantum wells, one or more multi-quantum wells, or one or more tunnel junctions, or (iv) the wavelength converter includes quantum dots.

Example 17. The light-emitting device of any one of Examples 1 through 16 wherein either: (i) the first output wavelength range includes one or more UV or visible wavelengths, the second output wavelength range includes one or more visible wavelengths, and the wavelength converter is arranged to absorb substantially all of the entering first output light, so that overall output of the light-emitting device includes light in only the second wavelength range; or (ii) both the first and second output wavelength ranges include visible wavelengths, and the wavelength converter is arranged to absorb only a portion of the entering first output light, so that overall output of the light-emitting device includes light in both the first and second wavelength ranges.

Example 18. The light-emitting device of any one of Examples 1 through 17 further comprising a light-emitting array that includes the light-emitting device and multiple additional similarly arranged light-emitting devices.

Example 19. The light emitting array of Example 18 wherein: (i) spacing of the light-emitting devices of the array is less than 1 millimeter, less than 500 microns, less than 200 microns, less than 100 microns, less than 50 microns, less than 20 microns, less than 10 microns, or less than 5 microns; or (ii) separation between light-emitting devices of the array is less than 200 microns, less than 100 microns, less than 50 microns, less than 20 microns, less than 10 microns, or less than 5 microns.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features – which features are shown, described, or claimed in the present application – including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either…or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth, or if a differing interpretation is implicit or inherent (e.g., some small integer quantities). For null quantities described by phrases such as “equal to zero,” “absent,” “eliminated,” “negligible,” “prevented,” and so forth (with or without terms such as “about,” “substantially,” and so forth), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled. Terms such as “parallel,” “perpendicular,” “orthogonal,” “flush,” “aligned,” and so forth shall be similarly interpreted (with or without terms such as “about,” “substantially,” and so forth).

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112(f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A wavelength-converted light-emitting device comprising:
(a) a semiconductor light-emitting diode (LED) having opposite first and second LED surfaces and LED sidewalls connecting the first and second LED surfaces and forming an angle less than about 70° with either the first or the second LED surface, the LED including (i) one or more light-emitting active regions arranged so as to emit first output light in a first output wavelength range, (ii) a first doped semiconductor layer between the first LED surface and the one or more active regions, and (iii) a second doped semiconductor layer between second LED surface and the one or more active regions;
(b) a wavelength converter, positioned on the second LED surface and the LED sidewalls, that absorbs at least a portion of the first output light that enters the wavelength converter and emits second output light in a second output wavelength range that is longer than the first output wavelength range;
(c) a first electrical contact on the first LED surface, the first contact being reflective over the first output wavelength range and in electrical contact with the first doped layer; and
(d) a second electrical contact, electrically isolated from the first contact, on at least a portion of the second LED surface or on a portion of the LED sidewalls, the second contact being transparent over the first output wavelength range and in electrical contact with the second doped layer.

2. The device of claim 1 wherein the LED sidewalls form an angle between about 40° and about 50° with either the first or second LED surface.

3. The device of claim 1 wherein the first contact includes a metallic layer in direct contact with the first doped layer.

4. The device of claim 1 wherein the first contact includes a metallic layer, an electrically insulating layer between the metallic layer and the LED, and one or more electrically conductive vias that connect the metallic layer to the first doped layer.

5. The device of claim 4 wherein the first contact includes a transparent conductive oxide (TCO) layer between the insulating layer and the first LED surface and in direct contact with the first doped layer, the first set of one or more vias connecting the metallic layer to the TCO layer.

6. The device of claim 4 wherein the insulating layer includes a dielectric multilayer reflector.

7. The device of claim 1 wherein the second LED surface includes patterning, roughening, scattering or diffractive elements, or a set of microlenses for coupling the first output light from the LED into the wavelength converter.

8. The device of claim 1 wherein thickness of the LED is less than 5 microns.

9. The device of claim 1 wherein the second LED surface includes a plurality of holes or depressions in the second doped layer at least partly filled with material of the wavelength converter.

10. The light-emitting device of claim 1 wherein (i) the LED includes one or more doped or undoped III-V, II-VI, or Group IV semiconductor materials, or mixtures, alloys, or compounds thereof, (ii) the first doped layer is a p-doped layer and the second doped layer is an n-doped layer, (iii) the one or more active regions include quantum dots, one or more quantum wells, one or more multi-quantum wells, or one or more tunnel junctions, or (iv) the wavelength converter includes quantum dots.

11. The light-emitting device of claim 1 further comprising a light-emitting array that includes the light-emitting device and multiple additional similarly arranged light-emitting devices.

12. A wavelength-converted light-emitting device comprising:
(a) a semiconductor light-emitting diode (LED) having opposite first and second LED surfaces and LED sidewalls connecting the first and second LED surfaces, the LED including (i) one or more light-emitting active regions arranged so as to emit first output light in a first output wavelength range, (ii) a first doped semiconductor layer between the first LED surface and the one or more active regions, and (iii) a second doped semiconductor layer between second LED surface and the one or more active regions;
(b) a first electrical contact on the first LED surface, the first contact being reflective over the first output wavelength range and in electrical contact with the first doped layer;
(c) a second electrical contact, electrically isolated from the first contact, on at least a portion of the LED sidewalls, the second contact being in electrical contact with the second doped layer and reflective over the first output wavelength range, and extending beyond the second LED surface so as to form a cavity bounded by the second substrate surface and the second electrical contact;
(d) a first electrically insulating layer on a portion of the LED sidewalls that separates the second electrical contact from the first electrical contact, the first doped layer, and the one or more active layers; and
(e) a wavelength converter, positioned on the second LED surface and at least partially fills the cavity, that absorbs at least a portion of the first output light that enters the wavelength converter and emits second output light in a second output wavelength range that is longer than the first output wavelength range.

13. The device of claim 12 wherein the LED sidewalls form an acute angle with either the first or the second LED surface.

14. The device of claim 12 wherein the first contact includes a metallic layer in direct contact with the first doped layer.

15. The device of claim 12 wherein the first contact includes a metallic layer, a second electrical insulating layer between the metallic layer and the LED, and one or more electrically conductive vias that connect the metallic layer to the first doped layer through the second insulating layer.

16. The device of claim 15 wherein the first contact includes a transparent conductive oxide (TCO) layer between the second insulating layer and the first LED surface and in direct contact with the first doped layer, the first set of one or more vias connecting the metallic layer to the TCO layer.

17. The device of claim 15 wherein the second insulating layer includes a dielectric multilayer reflector.

18. The device of claim 1 wherein the second LED surface includes patterning, roughening, scattering or diffractive elements, or a set of microlenses for coupling the first output light from the LED into the wavelength converter.

19. The device of claim 12 wherein the second LED surface includes a plurality of holes or depressions in the second doped layer at least partly filled with material of the wavelength converter.

20. The light-emitting device of claim 12 wherein (i) the LED includes one or more doped or undoped III-V, II-VI, or Group IV semiconductor materials, or mixtures, alloys, or compounds thereof, (ii) the first doped layer is a p-doped layer and the second doped layer is an n-doped layer, or (iii) the one or more active regions include quantum dots, one or more quantum wells, one or more multi-quantum wells, or one or more tunnel junctions, or (iv) the wavelength converter includes quantum dots.

21. The light-emitting device of claim 12 further comprising a light-emitting array that includes the light-emitting device and multiple additional similarly arranged light-emitting devices.
